(19) United States
(12) Patent Application Publication
(10) Pub. No.: US 2026/0114068 A1
(43) Pub. Date: Apr. 23, 2026

(54) IMAGE SENSOR PACKAGE

(71) Applicant: Samsung Electronics Co., Ltd., Suwon-si (KR)

(72) Inventors: Wansun Kim, Suwon-si (KR); Sunwoo Han, Suwon-si (KR); Shlege Lee, Suwon-si (KR); Yunseok Choi, Suwon-si (KR)

(21) Appl. No.: 19/181,531

(22) Filed: Apr. 17, 2025

(30) Foreign Application Priority Data
Oct. 17, 2024 (KR) 10-2024-0142240

(51) Int. Cl. H10F 39/00

(52) U.S. Cl. CPC H10F 39/811; H10F 39/804; H10F 39/8063

(57) ABSTRACT

An image sensor package includes a package substrate; an image sensor chip having first and second sides opposing each other in a first direction, and third and fourth sides opposing each other in a second direction, perpendicular to the first direction, and including a plurality of chip pads; a plurality of conductive wires; a first reinforcing structure; a dam; a transparent cover; and an encapsulant; a first region adjacent to the first side and including the first reinforcing structure disposed therein; and second to fourth regions adjacent to the second to fourth sides, respectively, and including at least a portion of the conductive wires disposed therein, wherein a volume ratio of the conductive wires to the dam in the first region is smaller than a volume ratio of the conductive wires to the dam in each of the second to fourth regions.

### CROSS-REFERENCE TO RELATED APPLICATION(S)

This U.S. non-provisional application claims benefit of priority to Korean Patent Application No. 10-2024-0142240 filed on Oct. 17, 2024 in the Korean Intellectual Property Office, the disclosure of which is incorporated herein by reference in its entirety.

### BACKGROUND

Example embodiments of the present disclosure relate to an image sensor package.

An image sensor may be a semiconductor sensor configured to receive light and to generate an electric signal, and may include a pixel array having a plurality of pixels, and a logic circuit for driving the pixel array and generating an image. Each of the pixels may include a photodiode and a pixel circuit configured to convert an electric charge generated by the photodiode into an electric signal.

### SUMMARY

An example embodiment of the present disclosure is to provide an image sensor package having improved reliability.

According to an example embodiment of the present disclosure, an image sensor package includes a package substrate including a plurality of upper pads; an image sensor chip disposed on the package substrate, having a first side and a second side opposing each other in a first direction, and a third side and a fourth side opposing each other in a second direction, perpendicular to the first direction, and including a plurality of chip pads adjacent to at least a portion of each of the first to fourth sides; a plurality of conductive wires each conductive wire of the plurality of conductive wires electrically connecting an upper pad of the plurality of upper pads to a corresponding chip pad of the plurality of chip pads corresponding to the plurality of upper pads, respectively, on the package substrate; a first reinforcing structure adjacent to the first side of the image sensor chip and spaced apart from the plurality of conductive wires; a dam disposed along the first to fourth sides of the image sensor chip and covering the plurality of chip pads and covering at least a portion of each conductive wire of the plurality of conductive wires; a transparent cover disposed on the dam; and an encapsulant covering at least a portion of each of the image sensor chip, the dam and the transparent cover on the package substrate; a first region adjacent to the first side and including the first reinforcing structure disposed therein; and second to fourth regions adjacent to the second to fourth sides, respectively, and including at least a portion of the conductive wires disposed therein, wherein a volume ratio of the conductive wires to the dam in the first region is smaller than a volume ratio of the conductive wires to the dam in each of the second to fourth regions.

According to an example embodiment of the present disclosure, an image sensor package includes a package substrate; an image sensor chip disposed on the package substrate, having a first side and a second side, and including a pixel array region including active pixels arranged therein, and a pad region positioned on an outer side of the pixel array region and including a plurality of chip pads disposed therein, where the plurality of chip pads includes a plurality of first chip pads and a plurality of second chip pads adjacent to the first side of the image sensor chip and the second side of the image sensor chip, respectively; a plurality conductive wires each conductive wire electrically connected to a corresponding second chip pad of the plurality of second chip pads on the second side of the image sensor chip; a reinforcing structure disposed adjacent to the plurality of first chip pads on the first side of the image sensor chip; a dam disposed on at least a portion of the pad region of the image sensor chip and covering at least a portion of each of the plurality of first chip pads and the plurality of second chip pads; a transparent cover disposed on the dam; and an encapsulant covering at least a portion of a side surface of the image sensor chip and a side surface of the dam on the package substrate, wherein the image sensor chip includes a microlens layer disposed on the active pixels on the pixel array region; a first protective layer having an opening exposing the plurality of first chip pads and the plurality of second chip pads on the pad region; and a second protective layer covering each of the microlens layer and the first protective layer, wherein the dam fills the opening exposing an upper surface of each first chip pad of the plurality of first chip pads and each second chip pad of the plurality of second chip pads, wherein the reinforcing structure is disposed adjacent to the plurality of first chip pads on an upper surface of the second protective layer, and wherein the conductive wires electrically connect each second chip pad of the plurality of second chip pads to the package substrate.

According to an example embodiment of the present disclosure, an image sensor package includes a package substrate including a plurality of upper pads; an image sensor chip disposed on the package substrate, having first to fourth sides, and including a plurality of inactive chip pads adjacent to the first side and a plurality of active chip pads adjacent to the second to fourth sides, respectively; a plurality of conductive wires, each conductive wire electrically connecting an upper pad of the plurality of upper pads of the package substrate to a corresponding active chip pad of the plurality of active chip pads of the image sensor chip on each of the second to fourth sides of the image sensor chip; a reinforcing structure disposed on the first side of the image sensor chip; a dam disposed along the first to fourth sides of the image sensor chip, and covering at least a portion of each inactive chip pad of the plurality of inactive chip pads, each active chip pad of the plurality of active chip pads, the reinforcing structure and each conductive wire of the plurality of conductive wires; a transparent cover disposed on the dam, and spaced apart from an upper surface of the image sensor chip; and an encapsulant covering at least a portion of each of the image sensor chip, the dam and the transparent cover on the package substrate, wherein the reinforcing structure includes a body portion, a lower adhesive film in contact with an upper surface of the image sensor chip below the body portion, and an upper adhesive film in contact with a lower surface of the transparent cover on the body portion, and wherein the dam surrounds a side surface of each of the body portion, the lower adhesive film, and the upper adhesive film.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a plan diagram illustrating an image sensor package according to an example embodiment of the present disclosure;

FIG. 1B is a cross-sectional diagram taken along line I-I′ in FIG. 1A;

FIG. 2A is an enlarged diagram illustrating a region corresponding to region ‘A’ of an image sensor package in FIG. 1B according to an example embodiment of the present disclosure;

FIG. 2B is an enlarged diagram illustrating regions corresponding to regions ‘B’ and ‘C’ of an image sensor package in FIG. 1B according to an example embodiment of the present disclosure;

FIG. 3A is a plan diagram illustrating an image sensor package according to an example embodiment of the present disclosure;

FIG. 3B is a cross-sectional diagram taken along line II-II′ in FIG. 3A;

FIG. 4 is a plan diagram illustrating an image sensor package according to an example embodiment of the present disclosure;

FIG. 5 is a plan diagram illustrating an image sensor package according to an example embodiment of the present disclosure;

FIG. 6A is a plan diagram illustrating an image sensor package according to an example embodiment of the present disclosure;

FIG. 6B is a cross-sectional diagram taken along line III-III′ in FIG. 6A;

FIG. 7A is a plan diagram illustrating an image sensor package according to an example embodiment of the present disclosure;

FIG. 7B is a cross-sectional diagram taken along line IV-IV′ in FIG. 7A;

FIG. 8A is a simulation graph comparing stress values accumulated in a sensor chip depending on the number of disposed bonding wires;

FIG. 8B is a simulation graph comparing stress values accumulated in a sensor chip depending on positions at which a reinforcing structure is disposed; and

FIGS. 9A to 9F are cross-sectional diagrams illustrating a process of manufacturing an image sensor package according to an example embodiment of the present disclosure.

### DETAILED DESCRIPTION

Hereinafter, embodiments of the present disclosure will be described as follows with reference to the accompanying drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “same,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed herein in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

As used herein, the term “dummy” is used to refer to a component that has the same or similar structure and shape as other components but does not have a substantial function and exists only as a pattern in the device.

The various pads of a device described herein may be conductive terminals connected to internal wiring of the device, and may transmit signals and/or supply voltages between an internal wiring and/or internal circuit of the device and an external source. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

Spatially relative terms, such as “below,” “lower,” “above,” “upper,” “top,” “bottom,” “front,” “back,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

A pixel, or unit pixel refers to a sensor element of an image sensor, and may refer to a smallest addressable light-sensing element of the image sensor.

As used herein the terms “on”, “over”, “covering” or “overlapping” are intended to mean that an element is over or aside another element. The elements may be touching or not. For example, there may be layers between layers that are “on” one another. An element “on” or “over” or “stacked” over or “covering” or “overlapping” another element need not cover an entire top surface of an element below to be considered “on” or “over” or “stacked” over or “covering” or “overlapping”. The terms are intended to encompass one element “on” or “over” or “stacked” over or “covering” or “overlapping” all, or any part of, an element below it.

As used herein, the words “surround”, “surrounding” and “surrounded” are intended to mean that an element is outside the other element. The elements may be touching or not. The surrounding element may or may not completely surround an inner element.

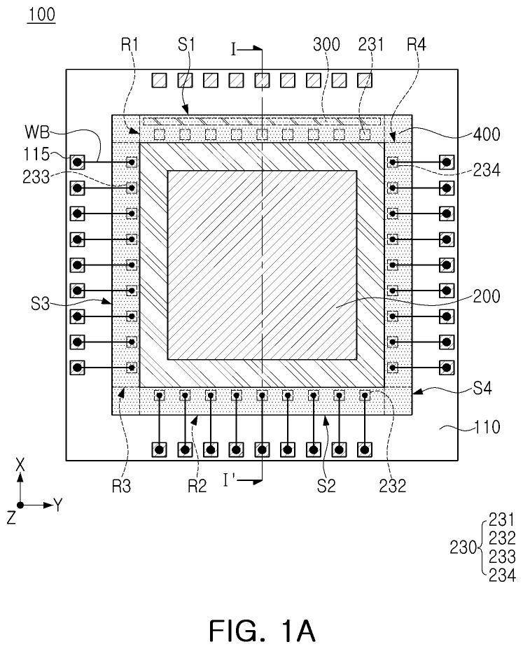

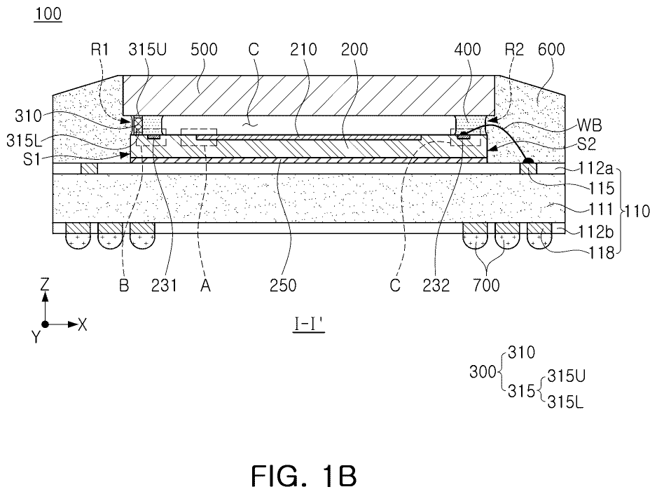

FIG. 1A is a plan diagram illustrating an image sensor package according to an example embodiment. FIG. 1B is a cross-sectional diagram taken along line I-I′ in FIG. 1A.

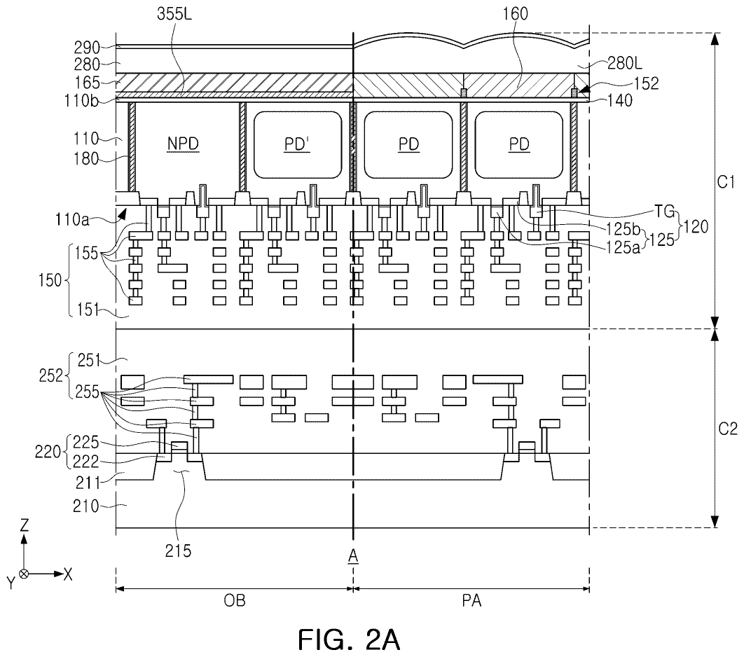

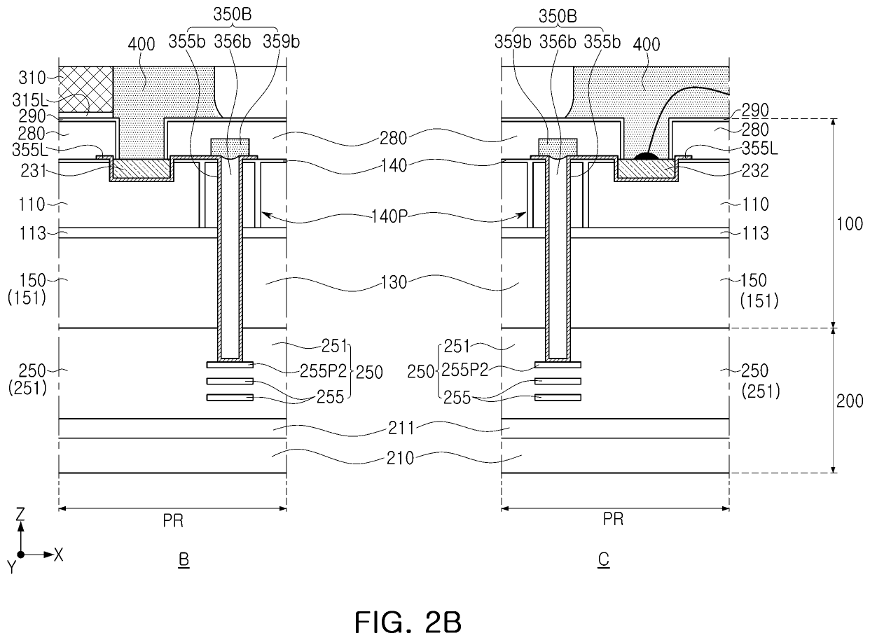

FIG. 2A is an enlarged diagram illustrating a region corresponding to region ‘A’ of an image sensor package in FIG. 1B according to an example embodiment. FIG. 2B is an enlarged diagram illustrating regions corresponding to regions ‘B’ and ‘C’ of an image sensor package in FIG. 1B according to an example embodiment. FIG. 2A is an enlarged diagram illustrating a pixel array region PA and a light-shielding region OB of an image sensor chip 200, and FIG. 2B may be an enlarged diagram illustrating a pad region PR of the image sensor chip 200.

Referring to FIGS. 1A to 2B, an image sensor package 100 in an example embodiment may include a package substrate 110, an image sensor chip 200, a conductive wire WB, a reinforcing structure 300, a dam 400, a transparent cover 500, an encapsulant 600, and external connection conductors 700.

The package substrate 110 may include a substrate body 111, an upper pad 115, a lower pad 118, and upper and lower passivation layers 112a and 112b. For example, the substrate body 111 may include silicone, ceramic, organic matter, glass, epoxy resin, or the like. In some example embodiments, the package substrate 110 may be configured as a printed circuit board (PCB). The substrate body 111 may include a single-layer wiring or multi-layer wirings. The wirings may electrically connect the upper pad 115 to the lower pad 118.

The image sensor chip 200 may be disposed on the package substrate 110 and may be mounted on the package substrate 110 as a wire bonding structure. The image sensor chip 200 may have a square shape or a rectangular shape on a plane, and may have a first side S1 and a second side S2 opposing each other in a first direction (e.g., X-axis direction), and a third side S3 and a fourth side S4 opposing each other in a second direction (e.g., Y-axis direction) intersecting the first direction. The image sensor chip 200 may include a plurality of chip pads 230, and the plurality of chip pads 230 may include first to fourth chip pads 231, 232, 233, and 234 in contact with the first to fourth sides S1, S2, S3, and S4, respectively.

The image sensor package 100 may have first to fourth regions R1, R2, R3, and R4 adjacent to first to fourth sides S1, S2, S3, and S4, respectively. In an example embodiment, the dam 400 may be disposed along the first to fourth sides S1, S2, S3, and S4 on an upper surface of the image sensor chip 200 (image sensor packages 100, 100B, 100C, 100D, and 100E).

In an example embodiment, the first region R1 may be a region covering the entirety of the first chip pads 231 aligned along the first side S1. For example, the long side of the first region R1 may have substantially the same length as that of one edge of an inner region of the upper surface of the image sensor chip 200, exposed from dam 400. The short side of the first region R1 may have the same length as a distance from the first side S1 of the image sensor chip 200 to one edge of the inner region opposing the first side S1. A reinforcing structure 300 may be disposed in the first region R1. In an example embodiment, the conductive wire WB may be disposed on the first region R1. The first region R1 may be understood as a three-dimensional space having a width, length, and height.

The second region R2 may be a region covering the entirety of the second chip pads 232 aligned along the second side S2. For example, the long side of the second region R2 may have substantially the same length as that of one edge of the inner region of the upper surface of the image sensor chip 200, exposed from the dam 400. The short side of the second region R2 may have the same length as a distance from the second side S2 of the image sensor chip 200 to the one edge of the inner region opposing the second side S2. The conductive wire WB may be disposed on the second region R2, and in example embodiments, a reinforcing structure 300 may be disposed in a region not overlapping the conductive wire WB in the vertical direction. The second region R2 may be understood as a three-dimensional space having a width, height, and height.

The second region R2 may be a region covering the entirety of the second chip pads 232 aligned along the second side S2. For example, the long side of the second region R2 may have substantially the same length as that of one edge of the inner region of the upper surface of the image sensor chip 200, exposed from the dam 400. The short side of the second region R2 may have the same length as the distance from the second side S2 of the image sensor chip 200 to the one edge of the inner region opposing the second side S2. The conductive wire WB may be disposed on the second region R2, and in example embodiments, the reinforcing structure 300 may be disposed in a region not overlapping the conductive wire WB in the vertical direction. The second region R2 may be understood as a three-dimensional space having a width, height, and height.

The third region R3 may be a region covering the entirety of the third chip pads 233 aligned along the third side S3. For example, the long side of the third region R3 may have substantially the same length as that of one edge of the inner region of the upper surface of the image sensor chip 200, exposed from the dam 400. The short side of the third region R3 may have the same length as a distance from the third side S3 of the image sensor chip 200 to one edge of the inner region opposing the third side S3. The conductive wire WB may be disposed on the third region R3. The third region R3 may be understood as a three-dimensional space having a width, height, and height.

The fourth region R4 may be a region covering the entirety of the fourth chip pads 234 aligned along the fourth side S4. For example, the long side of the fourth region R4 may be substantially the same length as that of one edge of the inner region of the upper surface of the image sensor chip 200, exposed from the dam 400. The short side of the fourth region R4 may be the same length as a distance from the fourth side S4 of the image sensor chip 200 to one edge of the inner region opposing the fourth side S4. The conductive wire WB may be disposed on the fourth region R4. The third region R3 may be understood as a three-dimensional space having a width, length, and height. In the image sensor package 100 in the example embodiment, the first to fourth regions R1, R2, R3, and R4 may be understood as regions filled by the dam 400 on the image sensor chip 200.

In the image sensor package 100 in the example embodiment, the first chip pads 231 may be referred to as inactive chip pads not electrically connected to the plurality of upper pads 115 of the package substrate 110, and the second to fourth chip pads 232, 233, and 234 may be referred to as active chip pads electrically connected to the plurality of upper pads 115 of the corresponding package substrate 110 through the conductive wires WB, but an example embodiment thereof is not limited thereto. In example embodiments, at least a portion of the first chip pads 231 may be active chip pads electrically connected to the plurality of upper pads 115 through wire bonding, and at least a portion of the second to fourth chip pads 232, 233, and 234 may be inactive chip pads not wire-bonded to the plurality of upper pads 115 and electrically insulated.

The image sensor chip 200 may be mounted such that the pixel array region PA may face upwardly, and may be adhered to the package substrate 110 by the adhesive layer 250. A plurality of chip pads 230 disposed in the pad region PR of the image sensor chip 200 may be electrically connected to a plurality of corresponding upper pads 115 of the package substrate 110 through the conductive wire WB.

The image sensor chip 200 may be disposed on the package substrate 110, and may be mounted on the package substrate 110 as a wire bonding structure. The image sensor chip 200 may be mounted such that the pixel array region PA may face upward, and may be adhered to the package substrate 110 by the adhesive layer 250. The plurality of chip pads 230 disposed in the pad region PR of the image sensor chip 200 may each be electrically connected to a corresponding upper pad of the plurality of corresponding upper pads 115 of the package substrate 110 through the conductive wire WB. The detailed description of the image sensor chip 200 may be described later.

The conductive wires WB may electrically connect each upper pad of the plurality of upper pads 115 of the package substrate 110 to a corresponding chip pad of the second to fourth chip pads 232, 233, 234 of the image sensor chip 200. The second to fourth chip pads 232, 233, and 234 may be aligned parallel to each other along the second to fourth sides S2, S3, and S4, respectively. For example, the second side S2 may extend in the second direction (e.g., Y-axis direction), and the second chip pads 232 may be aligned parallel to each other in the second direction. The conductive wires WB electrically connected to the second chip pads 232 may extend in the second direction intersecting the first direction in which the second chip pads 232 are aligned.

A volume of the conductive wires WB for the dam 400 in the first region R1 may be smaller than a volume of the conductive wires WB for the dam 400 in each of the second to fourth regions R2, R3, and R4. In an example embodiment, the bonding wires electrically connecting the pads to each other may not be disposed in the first region R1.

The reinforcing structure 300 may be adjacent to the first side S1 of the image sensor chip 200 and may be spaced apart from the first chip pads 231 in the first direction. The first chip pads 231 of the image sensor chip 200 may extend along the first side S1 in the second direction (e.g., Y-axis direction), and the reinforcing structure 300 may be disposed parallel to the direction in which the first chip pads 231 are aligned.

The reinforcing structure 300 may include a body portion 310 and an adhesive film 315L disposed below the body portion 310. The body portion 310 may have a form of a dummy chip including silicon (Si), but an example embodiment thereof is not limited thereto, and the reinforcing structure 300 may be a stiffener formed of a metal material.

The reinforcing structure 300 may be disposed adjacent to the inactive chip pads 231 on the first side S1 of the image sensor chip 200. The reinforcing structure 300 may be spaced apart from the conductive wires WB in the horizontal direction and may not overlap in the vertical direction, but an example embodiment thereof is not limited thereto. The reinforcing structure 300 may be disposed on an outer side of the image sensor chip 200 than the first chip pads 231, and in view of plane, the reinforcing structure 300 may be spaced apart from the first chip pads 231 in the first direction. The distance from the first side S1 to the reinforcing structure 300 may be smaller than the distance from the first side S1 to each of the first chip pads 231.

In the image sensor package 100, thermal stress may be applied to the dam 400 due to differences in thermal expansion coefficients between the image sensor chip 200 and the dam 460, and the transparent cover 500 and the dam 400. The thermal stress may be transferred to the second protective layer 290 of an upper end of the image sensor chip 200, in contact with the dam 400, cracks may occur in the second protective layer 290, and exterior defects may occur. Also, peeling may occur due to the cracks, and reliability of the image sensor chip 200 and the image sensor package 100 including the same may be reduced due to moisture or foreign matter from the outside.

The deformation due to thermal stress may be more severe in a region in which the bonding wire WB, which electrically connects the image sensor chip 200 to the package substrate 110, is not disposed. Accordingly, to prevent such deformation, the reinforcing structure 300 may be disposed on one side on which the bonding wire WB is not disposed, or on one side on which a relatively small number of bonding wires WBs are disposed. The reinforcing structure 300 may mitigate the difference in thermal expansion coefficient between components in the image sensor package and may reinforce rigidity, thereby reducing the influence of thermal stress, effectively preventing damage such as cracks, and mitigating the degree of deformation of the adhesive dam. Further, reliability of the entire image sensor package may improve in embodiments having a reinforcing structure 300.

The dam 400 may have a square ring shape surrounding a peripheral region of an upper surface of the image sensor chip 200. The dam 400 may be disposed along the first to fourth sides S1, S2, S3, and S4 of the image sensor chip 200, and may be disposed in a peripheral region of the upper surface of the image sensor chip 200, for example, the pad region PR. The dam 400 may be spaced apart from the pixel array region PA and may surround the pixel array region PA, but an example embodiment thereof is not limited thereto. The dam 400 may be disposed to cover at least a portion of each of the first to fourth chip pads 231, 232, 233, and 234 and the conductive wire of the image sensor chip 200. The dam 400 may have a lower surface in contact with the plurality of chip pads 230 of the image sensor chip 200 and an upper surface positioned opposite the lower surface. The lower surface of the dam 400 may be in contact with an upper surface of a second protective layer 290 extending conformally along the upper surface of the image sensor chip 200. A portion of the upper surface of the dam 560 may be in contact with the lower surface 540BS of the transparent cover 540, and the other portion of the upper surface of the dam may be in contact with the encapsulant 550, but an example embodiment thereof is not limited thereto. A width of the reinforcing structure 300 in the first direction (e.g., X-axis direction) may be smaller than a width of the dam 400 in the first direction, but an example embodiment thereof is not limited thereto.

The transparent cover 500 may be disposed on the image sensor chip 200. The dam 400 may be disposed along the outer side of the image sensor chip 200, and the transparent cover 500 may be disposed on the dam 400, such that at least a portion of the transparent cover 500 may overlap the dam 400 in the vertical direction. The dam 400 may support the transparent cover 500 on the image sensor chip 200. The transparent cover 500 may be spaced apart from an upper surface of the image sensor chip 200 by a height of the dam 400. At least a portion of the transparent cover 500 may be disposed to not overlap the dam 400 in the vertical direction, but an example embodiment thereof is not limited thereto. A spacing C may be present between the transparent cover 500 and the image sensor chip 200. The spacing C may be surrounded by the dam 400. For example, the transparent cover 500 may include transparent glass, transparent resin, or light-transmitting ceramic, but an example embodiment thereof is not limited thereto.

The encapsulant 600 may be disposed on the package substrate 110 and may encapsulate the image sensor chip 200, the conductive wire WB, and the transparent cover 500. Specifically, the encapsulant 600 may be disposed to cover the image sensor chip 200 from an upper surface of the package substrate 110 to a side surface of the transparent cover 500. Also, the encapsulant 600 may cover the conductive wire WB and the outer side surface of the dam 400. In the example embodiment, the encapsulant 600 may have a side surface substantially coplanar with a side surface of the package substrate 110. An upper surface of the encapsulant 600 may be substantially coplanar with an upper surface of the transparent cover 500, but an example embodiment thereof is not limited thereto, and a level of the upper surface of the encapsulant 600 may decrease in a direction away from the transparent cover 500. For example, the encapsulant 600 may be formed of an epoxy molding compound (EMC).

The external connection conductors 700 may be disposed on a lower surface of the package substrate 110. The external connection conductors 700 may be electrically connected to the image sensor chip 200 through the lower pads 118. The image sensor package 100 may be connected to an external device, such as a module substrate, a system board, or the like, through the external connection conductors 700. For example, the external connection conductors 700 may include a low melting point metal, such as tin (Sn) or a tin-silver-copper (Sn—Ag—Cu) alloy or a tin-aluminum-copper (Sn—Al—Cu) alloy including tin (Sn). In example embodiments, a lower passivation layer 112b may include a resist layer protecting the external connection conductors 580 from external physical and chemical damage.

Referring to FIG. 2A, the image sensor chip 200 may include a first chip C1 and a second chip C2 stacked and electrically connected to each other.

The first chip C1 may include a pixel array region PA in which a plurality of pixels are disposed in a two-dimensional array structure, and the second chip C2 may include a logic region in which logic devices are disposed. The logic devices included in the logic region may be electrically connected to pixels of the pixel array region and may provide signals to the pixels or may process signals output by the pixels. For example, the logic region may include at least one of a control register block, a timing generator, a ramp signal generator, a row driver, a readout circuit, or a buffer.

The first chip 103 may include a light-shielding region OB and a pad region PR in order from the pixel array region PA. The pixel array region PA and the light-shielding region OB may also be referred to as a sensor array region.

In the pixel array region PA, active pixels configured to receive light and generate an active signal may be arranged. In the light-shielding region OB, optical black pixels configured to block light and generate an optical black signal may be arranged. The light-shielding region OB may be disposed around the pixel array region PA, for example, but an example embodiment thereof is not limited thereto. In some example embodiments, dummy pixels may be disposed in the pixel array region PA in contact with the light-shielding region OB.

The pad region PR may be disposed around the light-shielding region PR. In some example embodiments, the pad region PR may be disposed adjacent to edges of the image sensor chip 200. In the example embodiment, the pad region PR may be disposed along four edges of the image sensor chip 200, or may be disposed at both side edges opposing each other or may be disposed to surround substantially the entirety of the first chip C1. The pad region PR may include a plurality of pads for connecting to an external device and may be configured to transmit and receive electrical signals between the image sensor chip 200 and the external device.

The arrangement of the pixel array region PA, the light-shielding region OB and the pad region PR may be varied if desired.

Referring to FIG. 2A, a first chip C1 of an image sensor chip 200 according to the example embodiments may include a first substrate 110 having a lower surface 110a and an upper surface 110b, a device isolation film 111 defining an active region on the lower surface 110a of the first substrate 110, first circuit devices 120 on the active region of the lower surface 110a of the first substrate 110, and a first wiring structure 150 between the lower surface of the first substrate 110 and the second chip C2. An upper surface 110b of the first substrate 110 may be referred to as a first surface or a back side, and the lower surface 110a of the first substrate 110 may be referred to as a second surface or a front side. The upper surface 110b of the first substrate 110 may be a light-receiving surface on which light is incident. The image sensor according to the example embodiment may be a back side illumination (BSI) image sensor.

As illustrated in FIG. 2A, in the pixel array region PA, the first chip C1 may include a surface insulating layer 140 on an upper surface 110b of the first substrate 110, a grid pattern 152 on the surface insulating layer 140, color filters 160 covering the surface insulating layer 140 and the grid pattern 152, and microlenses 280L on the color filters 160. Also, the first chip C1 may further include a conductive layer 355L on a horizontal insulating layer 140, a light-shielding filter layer 165 on the conductive layer 355L, and a first protective layer 280 and a second protective layer 240 covering the light-shielding filter layer 165 in the light-shielding region OB.

The second chip C2 may be disposed on a lower surface of the first chip C1. Referring to FIG. 2A, the second chip C2 may include a second substrate 210, a device isolation film 211 defining an active region 215 on the second substrate 210, second circuit devices 220 on the second substrate 210, and a second wiring structure 252 electrically connected to the second circuit devices 220. The second circuit devices 220 may include a device such as a transistor including a gate 225 and a source/drain 222.

The first substrate 110 may be a semiconductor substrate. For example, the first substrate 110 may be bulk silicone or a silicon-on-insulator (SOI). The first substrate 110 may be a silicone substrate, or may include other materials, such as silicon germanium (SiGe), indium antimonide, lead telluride, indium arsenide, indium phosphide, gallium arsenide, or gallium antimonide. Alternatively, the first substrate 110 may have a structure in which an epitaxial layer is formed on a base substrate. A plurality of unit pixels may be disposed in the first substrate 110 of the sensor array region SAR. For example, a plurality of pixels may be disposed in the pixel array region PA arranged two-dimensionally (e.g., in a matrix) on a plane including the first direction X and the second direction Y.

Each unit pixel may include a photoelectric conversion device PD. The photoelectric conversion devices PD may be disposed in the first substrate 110 of the pixel array region PA. The photoelectric conversion devices PD may generate electric charges in proportion to the amount of light incident to from the outside. For example, the photoelectric conversion devices PD may include at least one of a photodiode, a photo-transistor, a photo-gate, a pinned photodiode, an organic photodiode, a quantum dot, or a combination thereof, but an example embodiment thereof is not limited thereto.

The first circuit devices 120 may include a transfer gate TG and active devices 125. The active devices 125 may include a gate 125a and a source/drain 125b, respectively. The transfer gate TG may transfer electric charges from an adjacent photoelectric conversion device PD to an adjacent floating diffusion region, and the active devices 125 may be a transistor connected to the photoelectric conversion device PD and processing an electric signal, and may be at least one of a source follower transistor, a reset transistor, or a select transistor. The transfer gate TG may be a vertical transistor gate including a portion extending from a lower surface 110a of the first substrate 106 into the first substrate 110.

The pixel isolation pattern 130 may be disposed in the first substrate 110 of the sensor array region SAR. The pixel isolation pattern 130 may define a plurality of unit pixels. The pixel isolation pattern 130 may surround each of the photoelectric conversion device PD. The pixel isolation pattern 130 may be disposed in a grid form in view of the plane and may isolate the plurality of pixels from each other.

In the example embodiment, the pixel isolation pattern 130 may penetrate at least a portion of the first substrate 110. In some example embodiments, the pixel isolation pattern 130 may include a trench 130H extending from a lower surface 110a to an upper surface 110b, and may have a structure in which an insulating material is buried in the trench 130H. The pixel isolation pattern 130 may include an isolation insulating layer 131 formed on a sidewall of a trench 130H and a filling portion 135 surrounded by the isolation insulating layer 130a. For example, the isolation insulating layer 131 may include silicon oxide and the filling portion 135 may include polysilicon.

In the example embodiment, the pixel isolation pattern 130 may be connected to the device isolation film 111. The device isolation film 111 may be disposed on a lower surface 110a of the first substrate 110 as described above and may define an active region. For example, the device isolation film 111 may include an insulating material such as silicon oxide.

Referring to FIG. 2A, in the light-shielding region OB, a first reference region (or dummy photoelectric conversion devices) PD′ formed the same as the photoelectric conversion devices PD and a second reference region NPD in which the photoelectric conversion device PD is not formed may be provided. The second reference region NPD may be a comparison region not including the photoelectric conversion devices PD or a comparison region not including the photodiode of the photoelectric conversion devices PD. For example, the dummy photoelectric conversion devices PD′ may be disposed in the first substrate 110 of the light-shielding region OB in contact with the pixel array region PA, and may not be disposed in the first substrate 110 of the light-shielding region OB spaced apart from the pixel array region PA. In the light-shielding region OB, the first and second reference regions PD′ and NPD may be disposed in the first substrate 110 and may be isolated by the pixel isolation pattern 130.

The first wiring structure 150 may be disposed on a lower surface of the first substrate 110. The first substrate 110 and the first wiring structure 150 may form the first chip C1, wherein the first chip C1 may also be referred to as a “sensor chip.”

The first wiring structure 150 may include a first inter-wiring insulating layer 151 and a plurality of first wirings 155 on the first inter-wiring insulating layer 151. The number of layers of wirings and arrangement thereof, included in the first wiring structure 150 illustrated in the drawing, may be merely example. The plurality of first wirings 155 may include wiring patterns on different levels and vias electrically connecting the wiring patterns to the first circuit devices 120. The first inter-wiring insulating layer 151 may include at least one of, for example, silicon oxide, silicon nitride, silicon oxynitride, or a low-κ material having a dielectric constant lower than that of silicon oxide. The first wirings 155 may include at least one of, for example, tungsten (W), copper (Cu), aluminum (Al), gold (Au), silver (Ag), or alloys thereof.

The second substrate 210 may be bulk silicone or a silicon-on-insulator (SOI) the same as or similar to the first substrate 110. The second substrate 210 may be a silicone substrate, or may include other materials, such as silicon germanium, indium antimonide, lead telluride, indium arsenide, indium phosphide, gallium arsenide, or gallium antimonide. Alternatively, in the second substrate 210, an epitaxial layer may be formed on a base substrate. The second circuit devices 220 may be disposed on the second substrate 210. For example, the second circuit devices 220 may include transistors included in a control register block, a timing generator, a ramp signal generator, a row driver, a readout circuit, or a buffer.

The second wiring structure 252 may be disposed on the second substrate 210. For example, the second wiring structure 252 may be disposed between the first wiring structure 150 of the first chip C1 and the second substrate 210. The second substrate 210 and the second wiring structure 252 may be included in the second chip C2. Here, the second chip C2 may also be referred to as a “logic chip.”

The second wiring structure 252 may include a plurality of second wirings 255 on the second inter-wiring insulating layer 251 and the second inter-wiring insulating layer 251. The number of layers and the arrangement of the wirings included in the second wiring structure 252 illustrated in the drawing are merely an example. The plurality of first wirings 255 may include wiring patterns on different levels and vias electrically connecting the wiring patterns to the second circuit devices 220. The second wiring structure 252 may provide a path for transmitting and receiving electrical signals between the second circuit devices 220 and each unit pixel of the sensor array region SAR. Each of the second inter-wiring insulating layer 251 may include at least one of, for example, silicon oxide, silicon nitride, silicon oxynitride or a low-κ material having a dielectric constant lower than that of silicon oxide. The second wirings 255 may include at least one of, for example, tungsten (W), copper (Cu), aluminum (Al), gold (Au), silver (Ag) or alloys thereof. In the example embodiment, the first wiring structure 150 may be bonded to the second wiring structure 252. In some example embodiments, interfacial surfaces between the first and second wiring structures 150 and 252 may include a bonding insulating film. The bonding insulating film may include at least one of silicon oxide, silicon nitride, silicon oxynitride or silicon carbonitride (SiCN), but an example embodiment thereof is not limited thereto.

The surface insulating layer 140 may be disposed on the almost entire upper surface 110b of the first substrate 110. The surface insulating layer 140 may extend along the upper surface 110b of the first substrate 110 in the sensor array region SAR and also the upper surface 110b of the first substrate 110 in the peripheral region, for example, the inter-chip connection region CR and the pad region PR. The surface insulating layer 140 may include an insulating material. For example, the surface insulating layer 140 may include at least one of silicon oxide, silicon nitride, silicon oxynitride, aluminum oxide, hafnium oxide, or combinations thereof.

In some example embodiments, the surface insulating layer 140 may be multiple layers. The surface insulating layer 140 may function as an antireflective layer to prevent reflection of light incident to the first substrate 110, thereby improving a light reception rate of the photoelectric conversion device PD. Also, the surface insulating layer 140 functions as a planarizing film, such that the color filter 170 and the microlens layer 280L described later may be formed to have a uniform height. For example, the surface insulating layer 140 may include an aluminum oxide film, a hafnium oxide film, a silicon oxide film, a silicon nitride film, and a hafnium oxide film, stacked in order on the upper surface 110b of the first substrate 110.

The color filter 160 may be disposed on the surface insulating layer 140. The color filter 160 may be arranged to correspond to each unit pixel of the pixel array region PA. The color filter 160 may have various color filters depending on the unit pixel. For example, the color filter 160 may include a red color filter 160R, a green color filter 160G, and a blue color filter 160G. In some example embodiments, the color filters 160 may be arranged in a Bayer pattern. However, an example embodiment thereof is not limited thereto, and the color filters 170 may include a yellow filter, a magenta filter, and a cyan filter, and may further include a white filter.

In the example embodiment, a grid pattern 152 may be disposed between the color filters 160. The grid pattern 152 may be disposed on the surface insulating layer 140. The grid pattern 152 may be interposed between the color filters 160. In some example embodiments, the grid pattern 152 may be disposed to overlap the pixel isolation pattern 130 in the vertical third direction Z. In some example embodiments, the grid pattern 152 may include a conductive pattern and a low refractive index pattern. The conductive pattern may effectively prevent ESD failure by preventing electric charges generated by ESD from accumulating on the surface of the first substrate 110. The low refractive index pattern may improve light collection efficiency by refracting or reflecting light incident obliquely, thereby improving quality of the image sensor. For example, the conductive pattern may include at least one of titanium (Ti), titanium nitride (TiN), tantalum (Ta), tantalum nitride (TaN), tungsten (W), aluminum (Al), or copper (Cu), and the low refractive index pattern may include a low refractive index material having a refractive index lower than that of silicon (Si). For example, the low refractive index pattern may include at least one of silicon oxide, aluminum oxide, tantalum oxide, or a combination thereof.

The microlens layer 280L may be disposed on the color filter 160. The microlens layer 280L may be disposed on the active pixels in the pixel array region PA, and may include microlenses arranged to correspond to unit pixels of the pixel array region PA, respectively. Each of the microlenses may have a convex shape and may have a predetermined radius of curvature. Accordingly, the microlens may focus light incident to the photoelectric conversion devices PD. The microlens layer 280L may include, for example, an optically transparent resin. In some example embodiments, the microlens layer 280L may extend to a portion of the peripheral region (e.g., the light-shielding region OB).

Referring to FIG. 2A, the first chip C1 may further include a light-shielding filter layer 165. The light-shielding filter layer 165 may be disposed on the conductive layer 355L in the light-shielding region OB. In some example embodiments, the light-shielding filter layer 165 may extend from the light-shielding region OB to at least a portion of the pad region PR on the conductive layer 355L, but an example embodiment thereof is not limited thereto. The light-shielding filter layer 165 may form a light-shielding pattern shielding light together with the conductive layer 355L. The light-shielding filter layer 165 may be formed together with the color filters 160 and may have substantially the same thickness as a thickness of the color filters 160, but an example embodiment thereof is not limited thereto. The light-shielding filter layer 165 may include a blue color filter or a black filter. Thickness may refer to the thickness or height measured in a direction perpendicular to a top surface of the substrate.

In some example embodiments, the light-shielding region OB may be used to remove noise signals due to dark current. For example, in a state in which light is blocked by the conductive layer 355L and the light-shielding filter layer 165, the first reference region PD′ including the photodiode may be used as a reference pixel for removing noise caused by the photodiode. Also, in a state in which light is blocked by the conductive layer 355L and the light-shielding filter layer 165, the second reference region NPD not including the photodiode may be a region for checking process noise to remove noise caused by other components, not the photodiode.

Referring to FIG. 2B, each of the penetrating via structures 350B may include a via conductive layer 355b, a filling insulating film 356b, and a capping pattern 359b. A plurality of penetrating via structures 350A may be formed in via holes, respectively.

The via conductive layer 355b may be conformally formed on a sidewall and a bottom surface of the via hole in the pad region PR. The via conductive layer 355b may electrically connect the first or second pad 155P1 and 155P2 of the first wiring structure 150 to the first pad 255P1 of the second wiring structure 252. The via conductive layer 355b may be disposed in the via hole and may connect the first wiring 155 to the second wiring 255. The via conductive layer 355b may extend along a profile of a side surface and a lower surface of the first via hole H1.

In some example embodiments, the via conductive layer 355b may be formed together with the conductive layer 355L extending from the upper surface 110b of the first substrate 110, and may be connected to the conductive layer 355L or may be isolated from the conductive layer 355L and another via conductive layer. For example, the via conductive layer 355b may include at least one of titanium (Ti), titanium nitride (TiN), tantalum (Ta), tantalum nitride (TaN), tungsten (W), aluminum (Al), copper (Cu), or combinations thereof.

In some example embodiments, the filling insulating film 356b may be disposed on the via conductive layer 355b and may fill at least a portion of the first via hole H1. In some example embodiments, an upper surface of the filling insulating film 356b may be concave, which may be due to the characteristics of the process of forming the filling insulating film 356b (e.g., the deposition process and/or the planarization process), but an example embodiment thereof is not limited thereto. For example, the filling insulating film 356b may include a silicon-based insulating material (e.g., silicon nitride, silicon oxide, or silicon oxynitride) and a high-κ material (e.g., hafnium oxide, or aluminum oxide).

In some example embodiments, the capping pattern 359b may be disposed on the via conductive layer 355b and the filling insulating film 356b. For example, a portion of the capping pattern 359b may protrude from the upper surface of the via conductive layer 355b. In some example embodiments, the capping pattern 359b may not be provided.

The image sensor chip 200 according to the example embodiment may further include a first protective layer 280 extending from the microlens layer 280L and disposed on a peripheral region, for example, the light-shielding region OB, and the pad region PR.

The first protective layer 280 may be disposed on the light-shielding region OB, and the pad region PR and may provide a planar upper surface. Here, the first protective layer 280 may also be referred to as a planarization layer. In some example embodiments, the first protective layer 280 may extend from the light-shielding region OB to cover a plurality of penetrating via structures in the light-shielding filter layer 165 and the inter-chip connection region, may provide a planar upper surface, and may extend to the pad region PR. The first protective layer 280 may be formed such that the bonding pad 390 may be exposed in the pad region PR.

In some example embodiments, the first protective layer 280 may be formed together on the light-shielding region OB, the inter-chip connection region CR, and the pad region PR in a deposition process for forming the microlens layer 280L of the pixel array region PA. The first protective layer 280 may include the same material as that of the microlens layer 280L. For example, the first protective layer 280 may include a light-transmitting resin, such as a transparent photoresist material or a transparent thermosetting resin material.

The image sensor chip 200 according to the example embodiment may further include a second protective layer 290 formed on the microlens layer 280L and the first protective layer 280. The second protective layer 290 may extend along a surface of the microlens layer 280L and may be formed on an upper surface of the first protective layer 280. The second protective layer 290 may be formed relatively conformally. The second protective layer 290 may have a thickness smaller than that of the first protective layer 280. The second protective layer 290 may include a low temperature oxide (LTO). The second protective layer 290 may include an inorganic oxide, such as, for example, silicon oxide, titanium oxide, zirconium oxide, hafnium oxide, or a combination thereof. The second protective layer 290 may protect the microlens layer 280L from the outside. For example, by including an inorganic oxide film, the second protective layer 290 may protect the microlens layer 280L including an organic material. Also, the second protective layer 290 may improve quality of the image sensor chip 200 by improving the light collection efficiency of the microlenses of the microlens layer 280L. For example, the second protective layer 290 may be disposed in the region between the microlenses so as to reduce reflection, refraction, and scattering of incident light reaching the space between the microlenses.

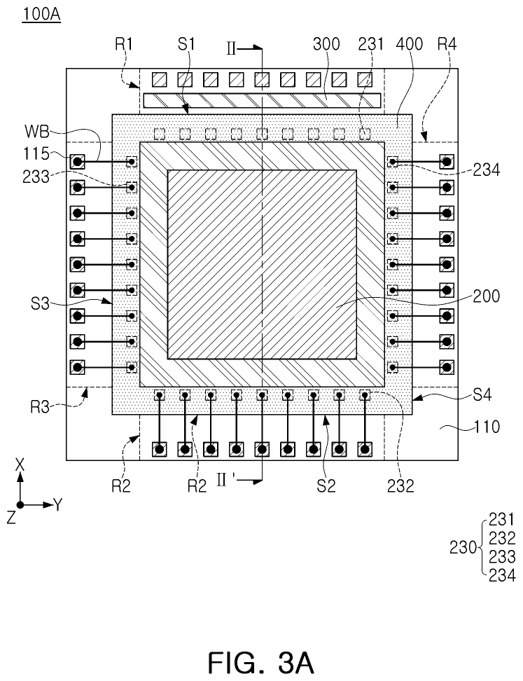

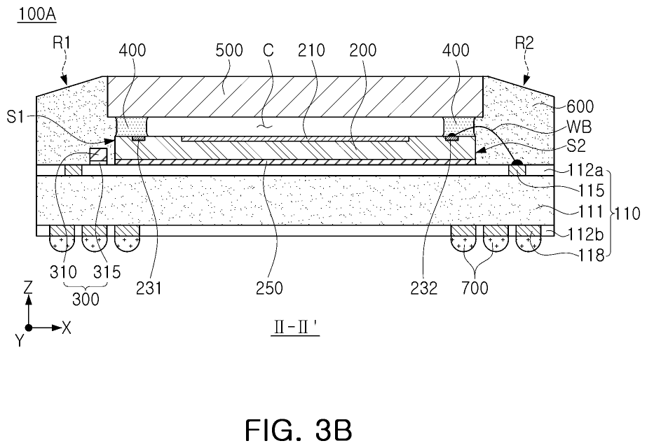

FIG. 3A is a plan diagram illustrating an image sensor package 100A according to an example embodiment. FIG. 3B is a cross-sectional diagram taken along line II-II′ in FIG. 3A.

Referring to FIGS. 3A and 3B, an image sensor package 100A in an example embodiment may be configured the same as or similar to the example described with reference to FIGS. 1A to 2B, other than the configuration in which the reinforcing structure 300 is disposed on an upper surface of the package substrate 110. The reinforcing structure 300 of the image sensor package 100A in the example embodiment may be disposed on the upper surface of the package substrate, and the encapsulant 600 may surround at least a portion of each of an upper surface and side surfaces of the reinforcing structure 300 on the upper surface of the package substrate 110.

In an example embodiment, a first region R1 may be a region covering the entirety of the upper pads 115 of the package substrate 110 disposed adjacent to the first side S1. For example, the long side of the first region R1 may have substantially the same length as that of one edge of the inner region of the upper surface of the image sensor chip 200, exposed from the dam 400. The short side of the first region R1 may have the same length as a distance from the first side S1 of the image sensor chip 200 to one edge of the package substrate 110 adjacent to the first side S1. The reinforcing structure 300 may be disposed in the first region R1, and in an example embodiment, the conductive wire WB may be disposed on the first region R1, but an example embodiment thereof is not limited thereto. The first region R1 may be understood as a three-dimensional space having a width, length, and height.

The second region R2 may be a region covering the entirety of the upper pads 115 of the package substrate 110 disposed adjacent to the second side S2. For example, the long side of the second region R2 may have substantially the same length as that of one edge of the inner region of the upper surface of the image sensor chip 200, exposed from the dam 400. The short side of the second region R2 may have the same length as the distance from the second side S2 of the image sensor chip 200 to one edge of the package substrate 110 adjacent to the second side S2. The conductive wire WB may be disposed in the second region R2, and in example embodiments, the reinforcing structure 300 may be disposed in a region not overlapping the conductive wire WB in the vertical direction. The second region R2 may be understood as a three-dimensional space having a width, length, and height.

The third region R3 may be a region covering the entirety of the upper pads 115 of the package substrate 110 disposed adjacent to the third side S3. For example, the long side of the third region R3 may have substantially the same length as that of one edge of the inner region of the upper surface of the image sensor chip 200, exposed from dam 400. The short side of the third region R3 may have substantially the same length as the distance from the third side S3 of the image sensor chip 200 to one edge of the package substrate 110 adjacent to the third side S3. The conductive wire WB may be disposed in the third region R3. The third region R3 may be understood as a three-dimensional space having a width, length, and height.

The fourth region R4 may be a region covering the entirety of the upper pads 115 of the package substrate 110 disposed adjacent to the fourth side S4. For example, the long side of the fourth region R4 may have substantially the same length as that of one edge of the inner region of the upper surface of the image sensor chip 200, exposed from dam 400. The short side of the fourth region R4 may be the same length as the distance from the fourth side S4 of the image sensor chip 200 to one edge of the package substrate 110 adjacent to the fourth side S4. The conductive wire WB may be disposed in the fourth region R4. The fourth region R4 may be understood as a three-dimensional space having a width, length, and height. In the image sensor package 100A in the example embodiment, the first to fourth regions R1, R2, R3, and R4 may be understood as regions filled by the encapsulant 600 on the package substrate 110.

The reinforcing structure 300 may be spaced apart from the first side S1 of the image sensor chip 200 in the first direction (e.g., X-axis direction). The reinforcing structure 300 may be adjacent to the first side S1 of the image sensor chip 200, and may be disposed on the upper surface of the package substrate 110, rather than the upper surface of the image sensor chip 200, such that rigidity of the region in which the bonding wire is not disposed may be reinforced, and simultaneously, the adhesive material for forming the dam 400 may be more easily dispensed along the pad region of the image sensor chip 200.

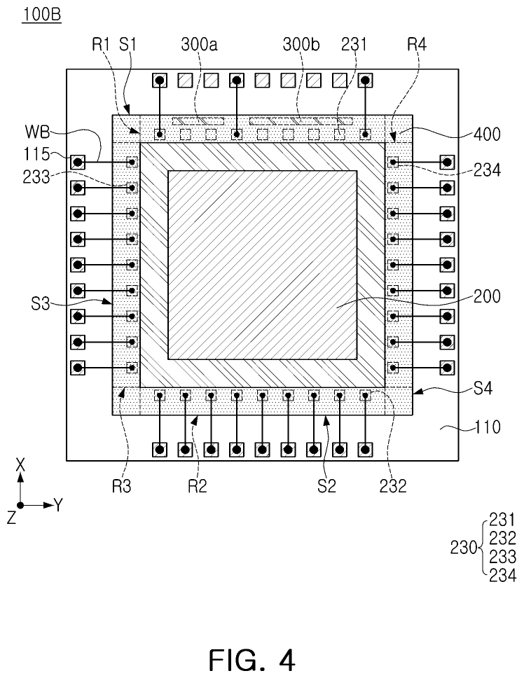

FIG. 4 is a plan diagram illustrating an image sensor package 100B according to an example embodiment.

Referring to FIG. 4, an image sensor package 100B in an example embodiment may be configured the same as or similar to the example described with reference to FIGS. 1a to 3b, other than the configuration in which at least a portion of the first chip pads 231 are electrically connected to a plurality of upper pads 115 through a conductive wire WB, and the reinforcing structure includes first and second reinforcing structures 300a, 300B. The first chip pads 231 may be disposed on the first side S1 of the image sensor chip 200 of the image sensor package 100B in the example embodiment. At least a portion of the first chip pads 231 may be active chip pads electrically connected to the plurality of upper pads 115 through the conductive wires WB, and the other portion of the first chip pads 231 may be inactive chip pads, or dummy chip pads, not electrically connected to the plurality of upper pads 115. The number of the first chip pads 231 may be nine as illustrated in the drawing, but the number is not limited thereto, and the active chip pads may be arranged irregularly. For example, a different number of inactive chip pads may be arranged between the active chip pads. The reinforcing structure 300 may include a plurality of portions of the first reinforcing structure 300a and the second reinforcing structure 300b. The first reinforcing structure 300a and the second reinforcing structure 300b may be spaced apart from each other in the second direction (e.g., Y-axis direction) so as not to overlap the conductive wires WB in the vertical direction. The reinforcing structure 300 may be selectively disposed in a region in which the number of the conductive wires WB or the volume of the conductive wires WB for the dam 400 is relatively small.

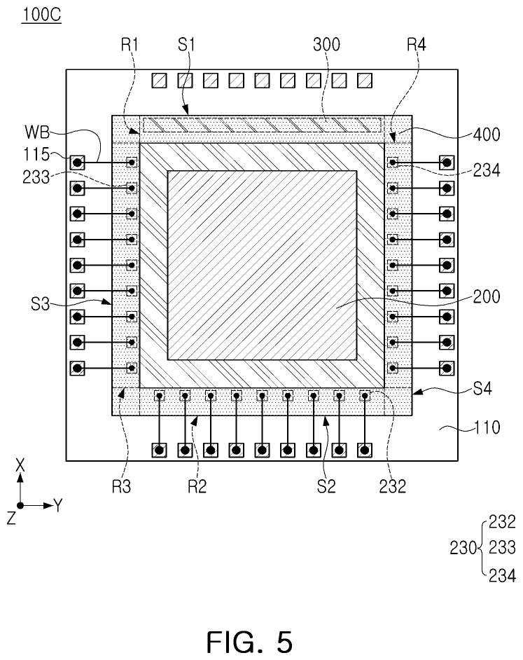

FIG. 5 is a plan diagram illustrating an image sensor package 100C according to an example embodiment.

Referring to FIG. 5, the image sensor package 100C in an example embodiment may be configured the same as or similar to the example described with reference to FIGS. 1 to 4, other than the configuration in which chip pads are not disposed on the first side S1. The image sensor package 100C in the example embodiment may have chip pads disposed on second to fourth sides S2, S3, and S4, other than the first side S1. The first side S1 may be a region in which conductive wires WB for wire bonding are not disposed, and a reinforcing structure 300 may be disposed therein. By disposing the reinforcing structure 300 in the region in which the chip pads are not formed, a width of the reinforcing structure 300 may be freely adjusted, and by increasing the width of the reinforcing structure 300, a difference in thermal expansion coefficients may be alleviated, thereby improving reliability of the package.

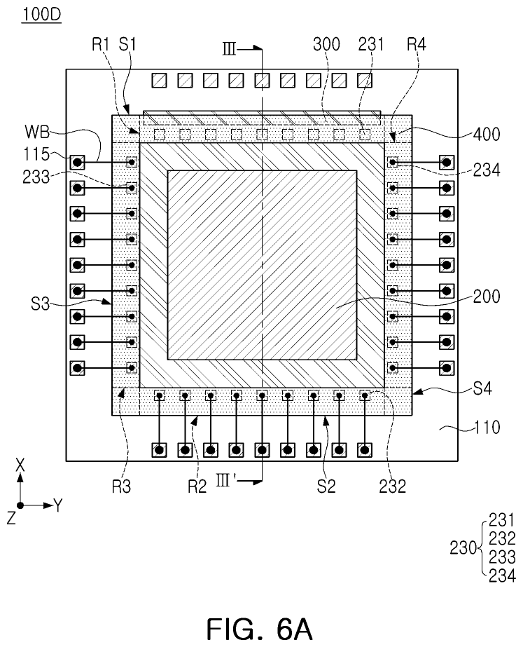

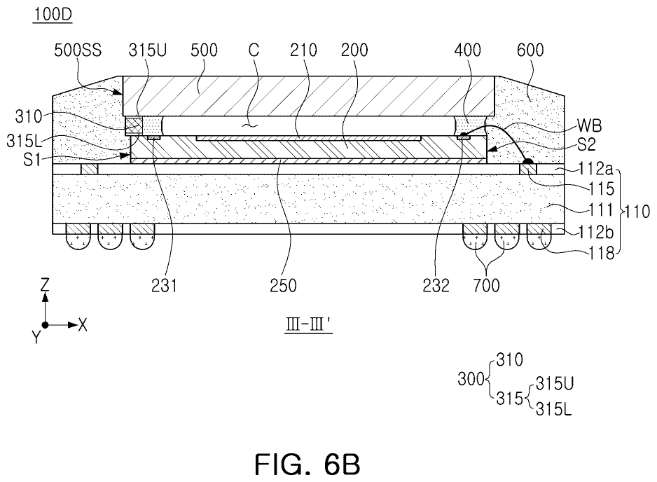

FIG. 6A is a plan diagram illustrating an image sensor package 100D according to an example embodiment.

Referring to FIGS. 6A and 6B, the image sensor package 100D in the example embodiment may be configured the same as or similar to the example described with reference to FIGS. 1 to 5, other than the configuration in which chip pads are not disposed on the first side S1. At least a portion of the reinforcing structure 300 of the image sensor package 100D in the example embodiment may have a structure extending from the first side S1 of the image sensor chip 200 to an outer side, and the at least a portion of the reinforcing structure 300 may be surrounded by the encapsulant 600. The reinforcing structure 300 may not be aligned on the first side S1 of the image sensor chip 200, and a width of the reinforcing structure 300 may be freely adjusted, and by increasing the width of the reinforcing structure 300, a difference in thermal expansion coefficients may be alleviated, thereby improving reliability of the package.

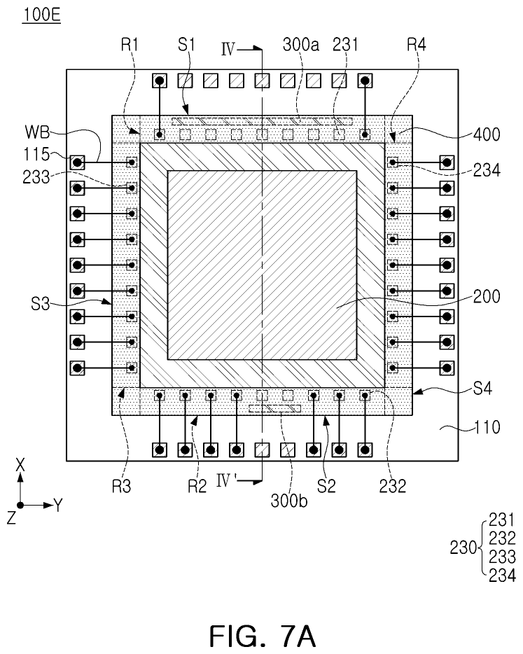

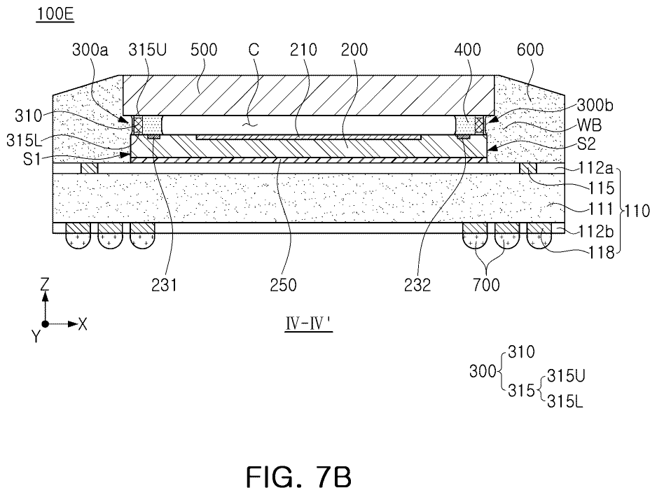

FIG. 7A is a plan diagram illustrating an image sensor package 100E according to an example embodiment. FIG. 7B is a cross-sectional diagram taken along line IV-IV′ in FIG. 7A

Referring to FIGS. 7A and 7B, the image sensor package 100E in an example embodiment may be configured the same as or similar to the example described with reference to FIGS. 1A to 6B, other than the configuration in which the first reinforcing structure 300A and the second reinforcing structure 300B are disposed on the first side S1 and the second side S2, respectively. The image sensor package 100E in the example embodiment may have first chip pads 231 disposed on the first side S1 of the image sensor chip 200, and second chip pads 232 disposed on the second side S2. At least a portion of each of the first chip pads 231 and the second chip pads may be active chip pads electrically connected to a plurality of the upper pads 115 through conductive wires WB, and the other portion of each of the first chip pads 231 and the second chip pads 232 may be inactive chip pads, or dummy chip pads, not electrically connected to the plurality of upper pads 115. In the example embodiment, the number of the first chip pads 231 and the second chip pads 232 is not limited to the example illustrated in FIG. 7A. In the image sensor package 100E in the example embodiment, the number of conductive wires WB disposed in the first side S1 may be less than the number of conductive wires WB disposed in each of the second side S2. The first reinforcing structure 300A may be spaced apart from the conductive wires WB adjacent to the first side S1, and the second reinforcing structure 300B may be spaced apart from the conductive wires WB adjacent to the second side S2. The first reinforcing structure 300A may have a first volume, and the second reinforcing structure 300B may have a second volume smaller than the first volume.

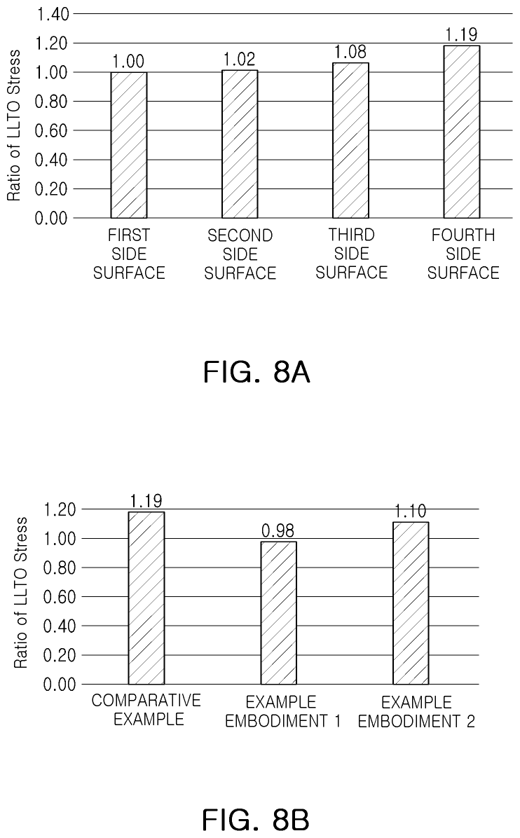

FIG. 8A is a simulation graph comparing stress values accumulated in a sensor chip depending on the number of disposed bonding wires. FIG. 8B is a simulation graph comparing stress values accumulated in a sensor chip depending on positions at which a reinforcing structure is disposed.

FIG. 8A is a simulation graph comparing stress values applied to each side surface of the image sensor chip as different numbers of bonding wires are disposed on four side surfaces of the image sensor chip.

FIG. 8A may be a graph comparing the degree of thermal stress applied to the LLTO (low low temperature oxide) layer positioned in an uppermost portion of each side surface of the image sensor chip. LLTO may be a region corresponding to the second protective layer 290 in the image sensor package 100 in the example embodiment, and may correspond to a component in contact with the lower surface of the dam 400. In this simulation, the image sensor chip may have different numbers of bonding wires disposed on the first to fourth side surfaces, respectively, and accordingly, volume ratios of bonding wires to adhesive dams disposed adjacent to the first to fourth sides surfaces, respectively, may be different. For example, the volume ratio of the bonding wire to the adhesive dam on the first side surface may be approximately 2%, the volume ratio of the bonding wire to the adhesive dam on the second side surface may be approximately 1.7%, the volume ratio of the bonding wire to the adhesive dam on the third side surface may be approximately 1.25%, and the volume ratio of the bonding wire to the adhesive dam on the fourth side surface may be 0%. The volume ratio of the bonding wire to the adhesive dam on each side surface may decrease in the order of the first side surface, the second side surface, the third side surface, and the fourth side surface, and the bonding wire may not be disposed on the fourth side surface.

In FIG. 8A, the stress values applied to the LLTO on side surfaces of the image sensor chip 200, respectively, may be understood as comparative values for the first side surface in which the volume ratio of the bonding wire to the adhesive dam on the image sensor chip 200 is the largest, approximately 2%. For example, when the stress value applied to LLTO on the first side surface is 1.00, it may be observed that the stress value applied to LLTO on the second side surface is 1.02, the stress value applied to LLTO on the third side surface is 1.08, and the stress value applied to LLTO on the fourth side surface is 1.19. Accordingly, it may be observed that the stress value applied to LLTO on each side surface increases as the volume ratio of the bonding wire to the adhesive dam decreases on each side surface of the image sensor chip. For example, according to the simulation graph in FIG. 8A, it may be observed that, as the number of bonding wires disposed on the side surface increases, the degree of thermal stress applied to the LLTO layer may decrease, which may be because the difference in thermal expansion coefficients between the sensor chip and the dam is alleviated or between the sensor chip and the package substrate as the number of bonding wires formed of metal materials increases.

FIG. 8B is a simulation graph comparing stress values applied to side surfaces depending on a position in which the reinforcing structure is disposed based on the comparative example in which the bonding wire is not disposed for each side surface of the image sensor chip.

In FIG. 8B, in the comparative example, in example embodiment 1 and in example embodiment 2, the reinforcing structure 300 is present or not or the position in which the reinforcing structure 300 is disposed, is different.

The comparative example may be understood as the stress value applied to the LLTO of the one side surface when the bonding wire is not disposed on one side surface of the image sensor chip. The value indicated by the comparative example in the graph in FIG. 8B may be understood as the simulation result value corresponding to the fourth side surface in FIG. 8A.

In the example embodiment, the reinforcing structure 300 may be disposed on one side of the upper surface of the image sensor chip 200. The one side may correspond to one side of side surfaces of the image sensor chip 200 on which the bonding wire is not disposed. In example embodiment 1, the reinforcing structure 300 may have a structure surrounded by the dam 400. The value that example embodiment 1 indicates in the graph in FIG. 8B may be a stress value applied to LLTO of the one side, and may be understood as a simulation result value corresponding to the example embodiment illustrated in FIGS. 1A and 1B.

In example embodiment 2, the reinforcing structure 300 may be disposed adjacent to one side of the image sensor chip 200 on the upper surface of the package substrate 110, and the one side may correspond to one side of side surfaces of the image sensor chip 200 on which the bonding wire is not disposed. In example embodiment 2, reinforcing structure 300 may be surrounded by an encapsulant 600. The value that example embodiment 2 indicates in the graph in FIG. 8B may a stress value applied to LLTO of the one side, and may be understood as a simulation result value corresponding to the example embodiment illustrated in FIGS. 3A and 3B.

In FIG. 8B, the stress values applied to LLTO on side surfaces of the image sensor chip 200, respectively, according to example embodiment 1 and example embodiment 2 may be understood as comparative values for the comparative example. For example, in the comparative example, when the stress value applied to the LLTO of one side is 1.19, it may be observed that the stress value applied to the LLTO of one side in example embodiment 1 is 0.98, and the stress value applied to the LLTO of one side in example embodiment 2 is 1.10. Accordingly, it may be observed that, by disposing the reinforcing structure on one side of each of the side surfaces of the image sensor chip in which the bonding wire is not disposed, the stress value applied to the LLTO of the one side decreases. Also, in example embodiment 1, it may be observed that the stress value applied to the LLTO of one side decreases more significantly when the reinforcing structure is disposed on an upper surface of the image sensor chip.

The image sensor package may have a region in which the bonding wire is not disposed or is disposed irregularly, and by disposing the reinforcing structure in the region, rigidity of the adhesive dam on the image sensor chip may be reinforced, and further, the stress applied to the LLTO layer of the image sensor chip may be reduced, such that an image sensor package having improved reliability may be provided.

In this case, the volume ratio of the reinforcing structure 300 to the adhesive dam may be about 5% to about 40%, about 8% to about 32%, or about 15% to about 25%, but an example embodiment thereof is not limited thereto. For example, when the volume ratio is less than about 5%, the degree of rigidity of the dam 400 reinforced by the reinforcing structure 300 may be relatively low, and the degree of thermal stress applied to the dam 400 may be insufficiently alleviated. For example, when the volume ratio exceeds about 40%, the volume of the reinforcing structure 300 relative to the volume of the dam 400 may be excessively large, such that the dam 400 supporting and fixing the transparent cover 500 may not be sufficiently disposed on the image sensor chip 200.

In example embodiment 1, the reinforcing structure 300 may be disposed on one side of the upper surface of the image sensor chip 200. The reinforcing structure 300 in example embodiment 1 may have a structure surrounded by the dam 400, and the region in which the reinforcing structure 300 is disposed on the dam 400 may be referred to as the first reinforcement region.

In example embodiment 2, the reinforcing structure 300 may be disposed adjacent to one side of the image sensor chip 200 on the upper surface of the package substrate 110. In example embodiment 2, the reinforcing structure 300 may be surrounded by an encapsulant 600, and in the encapsulant 600, the region in which reinforcing structure 300 is disposed may be referred to as the second reinforcement region.

In this case, for example, in the first reinforcement region in example embodiment 1, the volume ratio of the reinforcing structure 300 to the dam 400 may be 30%, and in the second reinforcement region in example embodiment 2, the volume ratio of the reinforcing structure 300 to the encapsulant 600 may be 10%. The difference between the above-described volume ratios may be because the volumes of reinforcing structure 300 in example embodiment 1 and example embodiment 2 may are the same, and the volumes of the dam 400 and the encapsulant 600 are different.

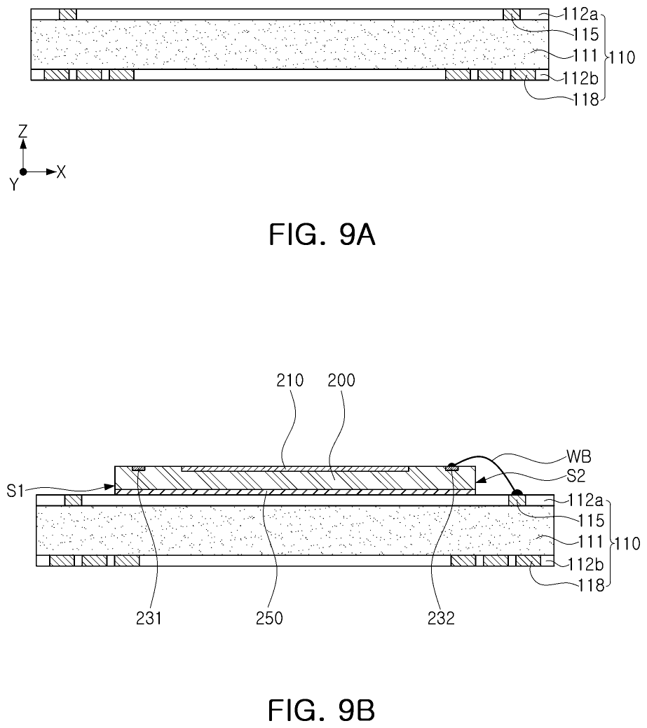

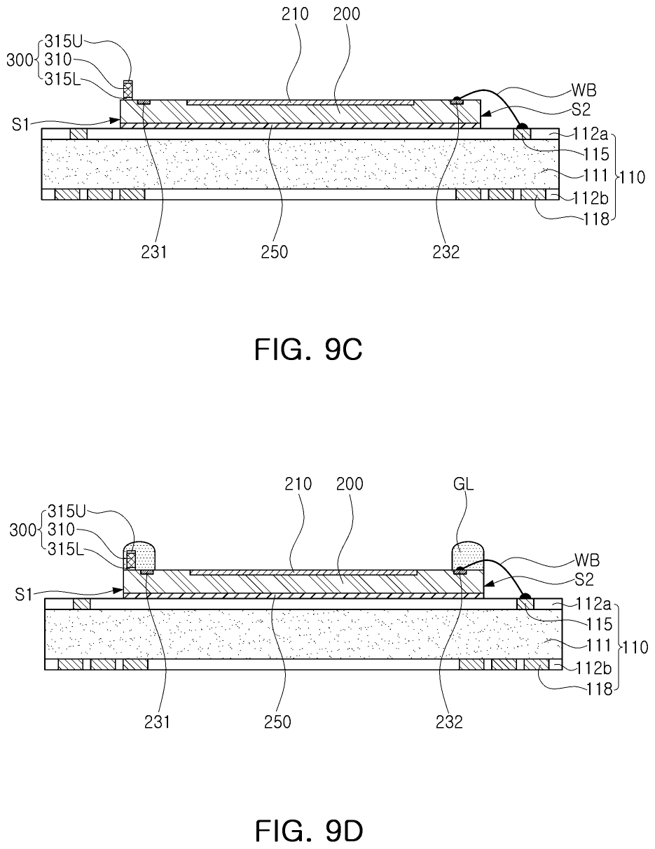

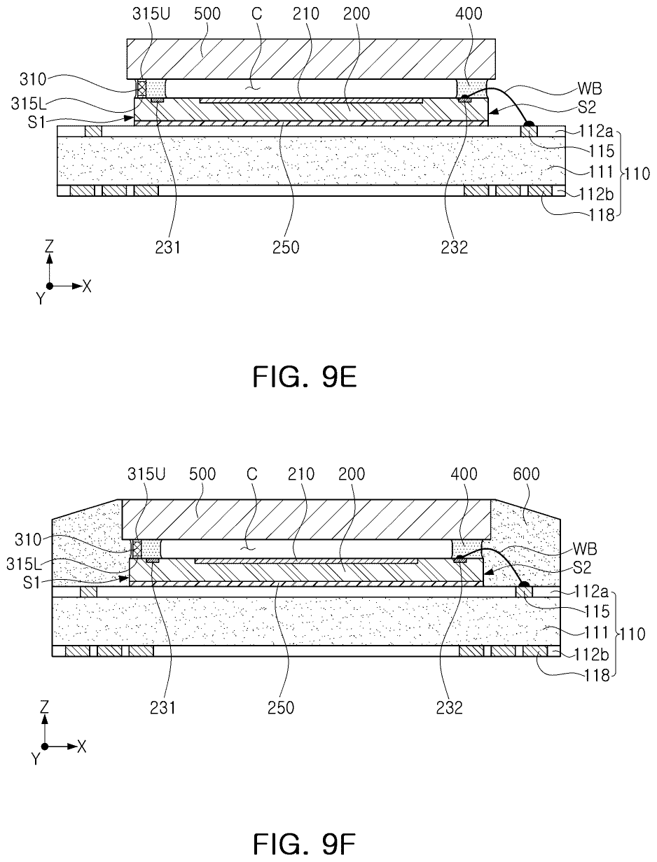

FIGS. 9A to 9F are cross-sectional diagrams illustrating a process of manufacturing an image sensor package 100 according to an example embodiment.

Referring to FIG. 9A, a package substrate 110 may be prepared. The package substrate 110 may include a substrate body 111, an upper pad 115, a lower pad 118, and upper and lower passivation layers 112a and 112b. The upper pad 115 and the lower pad 118 may be electrically connected to each other by a wiring structure (not illustrated) in the substrate body 111. An upper surface of the upper pad 115 may be exposed from the upper passivation layer 112a, and a lower surface of the lower pad 118 may be exposed from the lower passivation layer 112b.

Referring to FIG. 9B, an image sensor chip 200 may be disposed on the package substrate 110, and the image sensor chip 200 may be electrically connected to the package substrate 110 through the conductive wire WB. The image sensor chip 200 may be attached to the package substrate 110 by the adhesive layer 250 disposed on a lower end of the image sensor chip 200. The conductive wire WB may be electrically connected only to a portion of a plurality of chip pads 230 of the image sensor chip 200. For example, the conductive wire WB may electrically connect chip pads of the second to fourth chip pads 232, 233, and 234 disposed adjacent to the second to fourth side S2, S3, and S4 of the image sensor chip 200, to the corresponding upper pads of the plurality of upper pads 115 of the package substrate 110.

Referring to FIG. 9C, the reinforcing structure 300 may be disposed on the image sensor chip 200.

The reinforcing structure 300 may be disposed along the first side S1 of the image sensor chip 200, and may be spaced apart from the first chip pads 231 in contact with the first side S1. The reinforcing structure 300 may be disposed so as not to overlap the first chip pads 231 in the vertical direction. The reinforcing structure 300 may include a body portion 310 and a lower adhesive film 315L attaching the body portion 310 to an upper surface of each of the package substrate or the image sensor chip. In example embodiments, the reinforcing structure 300 may further include an upper adhesive film 315U attached to a lower surface of a transparent cover 500 disposed in a subsequent process. Together, lower adhesive film 315L and upper adhesive film 315U, may be labeled as adhesive film 315.

Referring to FIG. 9D, the adhesive material GL may be dispensed along the first to fourth sides S1, S2, S3, and S4 of the image sensor chip 200. The image sensor chip 200 may have a pixel array region PA in which active pixels are arranged positioned at the center, and an adhesive material GL surrounding the pixel array region PA may be disposed on an upper surface of the image sensor chip 200. The adhesive material GL may be dispensed on an upper surface of the image sensor chip 200 in an amount sufficient to cover both the side surface and the upper surface of the reinforcing structure 300.

Referring to FIG. 9E, a transparent cover 540 may be disposed on the adhesive material GL, and the adhesive material GL may be cured, thereby forming a dam 400.

The transparent cover 500 may be disposed on the adhesive material (GL, see FIG. 9D) and the reinforcing structure 300. The lower surface of the transparent cover 500 may be in contact with the upper surface of the upper adhesive film 315U of the reinforcing structure 300, but an example embodiment thereof is not limited thereto, and in example embodiments, the upper surface of the body portion 310 may be spaced apart from the lower surface of the transparent cover 500 in the vertical direction, and the adhesive material GL may extend between the body portion 310 and the transparent cover 500. The dam 400 may be formed by curing the adhesive material (GL, see FIG. 9D) disposed between the image sensor chip 200 and the transparent cover 500 in the previous process (see FIG. 9D). In example embodiments, the side surface of the dam 400 may have a curved shape, concave toward the dam 400, but an example embodiment thereof is not limited thereto.

Referring to FIG. 9F, an encapsulant 600 may be formed. The encapsulant 600 may cover at least a portion of each of the image sensor chip 200, the dam 400, the conductive wire WB, and the transparent cover 500 on the package substrate 110. The encapsulant 600 may cover at least a portion of the side surface of the dam 400, and the encapsulant 600 may cover at least a portion of the side surface of the transparent cover 500.

Referring to FIGS. 1A and 1B, by disposing external connection conductors 700 below the package substrate 110, the image sensor package 100 in the example embodiment may be formed. The external connection conductors 700 may be attached to the lower surface of the lower pads 118.

According to the aforementioned example embodiments, by including a reinforcing structure disposed adjacent to one side region of the image sensor chip in which the bonding wire is not connected, influence of thermal stress may be reduced, such that damage such as cracks may be effectively prevented.

While the example embodiments have been illustrated and described above, it will be configured as apparent to those skilled in the art that modifications and variations could be made without departing from the scope of the present disclosure.

What is claimed is:

1. An image sensor package, comprising:
a package substrate including a plurality of upper pads;
an image sensor chip disposed on the package substrate, having a first side and a second side opposing each other in a first direction, and a third side and a fourth side opposing each other in a second direction, perpendicular to the first direction, and including a plurality of chip pads adjacent to at least a portion of each of the first to fourth sides;
a plurality of conductive wires each conductive wire of the plurality of conductive wires electrically connecting an upper pad of the plurality of upper pads to a corresponding chip pad of the plurality of chip pads;
a first reinforcing structure adjacent to the first side of the image sensor chip and spaced apart from the plurality of conductive wires;
a dam disposed along the first to fourth sides of the image sensor chip and covering the plurality of chip pads and covering at least a portion of each conductive wire of the plurality of conductive wires;
a transparent cover disposed on the dam; and
an encapsulant covering at least a portion of each of the image sensor chip, the dam and the transparent cover on the package substrate;
a first region adjacent to the first side and including the first reinforcing structure disposed therein; and
second to fourth regions adjacent to the second to fourth sides, respectively, and including at least a portion of the conductive wires disposed therein,
wherein a volume ratio of the conductive wires to the dam in the first region is smaller than a volume ratio of the conductive wires to the dam in each of the second to fourth regions.

2. The image sensor package of claim 1, wherein the first reinforcing structure does not overlap the conductive wires in a vertical direction.

3. The image sensor package of claim 1, wherein the first reinforcing structure includes a body portion and an adhesive film disposed below the body portion.

4. The image sensor package of claim 3, wherein the body portion includes silicon (Si).

5. The image sensor package of claim 3, wherein the body portion includes a metal material.

6. The image sensor package of claim 1,
wherein the plurality of chip pads include first chip pads adjacent to the first side of the image sensor chip, and
wherein the first reinforcing structure is spaced apart from the first chip pads in the first direction.

7. The image sensor package of claim 6, wherein the first chip pads are electrically isolated from the plurality of upper pads.

8. The image sensor package of claim 1,
wherein the first reinforcing structure is disposed on an upper surface of the image sensor chip, and
wherein the dam surrounds at least a portion of each of a first upper surface and a first side surface of the first reinforcing structure on the first region.

9. The image sensor package of claim 1,
wherein the first reinforcing structure is disposed on an upper surface of the package substrate, and
wherein the encapsulant surrounds at least a portion of each of a first upper surface and a first side surface of the first reinforcing structure on the first region.

10. The image sensor package of claim 9, wherein the first reinforcing structure is spaced apart from the first side of the image sensor chip in the first direction.

11. The image sensor package of claim 1,
wherein the plurality of chip pads include a plurality of first chip pads adjacent to the first side of the image sensor chip, and
wherein at least one conductive wire of the plurality of conductive wires electrically connects at least one upper pad of the plurality of upper pads to a corresponding first chip pad of the plurality of first chip pads.

12. The image sensor package of claim 11, further comprising:
a second reinforcing structure adjacent to the first side of the image sensor chip,
wherein the second reinforcing structure is spaced apart from the first reinforcing structure in the second direction.

13. The image sensor package of claim 1, wherein the plurality of chip pads are not disposed on the first side of the image sensor chip.

14. The image sensor package of claim 1, wherein at least a portion of the first reinforcing structure is in contact with the encapsulant.

15. The image sensor package of claim 1, further comprising:
a second reinforcing structure disposed adjacent to the second side of the image sensor chip,
wherein the second reinforcing structure has a second volume smaller than a first volume of the first reinforcing structure.

16. The image sensor package of claim 15,
wherein the plurality of chip pads include second chip pads disposed on the second side of the image sensor chip, and
wherein the second reinforcing structure is spaced apart from at least a portion of the second chip pads, not electrically connected to the plurality of upper pads among the second chip pads, in the first direction.

17. The image sensor package of claim 1, further comprising:
external connection conductors electrically connected to the package substrate and the image sensor chip below the package substrate.

18. An image sensor package, comprising:
a package substrate;
an image sensor chip disposed on the package substrate, having a first side and a second side, and including a pixel array region including active pixels arranged therein, and a pad region positioned on an outer side of the pixel array region and including a plurality of chip pads disposed therein, where the plurality of chip pads include a plurality of first chip pads and a plurality of second chip pads adjacent to the first side of the image sensor chip and the second side of the image sensor chip, respectively;
a plurality of conductive wires each conductive wire electrically connected to a corresponding second chip pad of the plurality of second chip pads on the second side of the image sensor chip;
a reinforcing structure disposed adjacent to the plurality of first chip pads on the first side of the image sensor chip;
a dam disposed on at least a portion of the pad region of the image sensor chip and covering at least a portion of each of the plurality of first chip pads and the plurality of second chip pads;
a transparent cover disposed on the dam; and
an encapsulant covering at least a portion of a side surface of the image sensor chip and a side surface of the dam on the package substrate,
wherein the image sensor chip includes:
a microlens layer disposed on the active pixels on the pixel array region;
a first protective layer having an opening exposing the plurality of first chip pads and the plurality of second chip pads on the pad region; and
a second protective layer covering each of the microlens layer and the first protective layer,
wherein the dam fills the opening exposing an upper surface of each first chip pad of the plurality of first chip pads and each second chip pad of the plurality of second chip pads,
wherein the reinforcing structure is disposed adjacent to the plurality of first chip pads on an upper surface of the second protective layer, and
wherein the conductive wires electrically connect each second chip pad of the plurality of second chip pads to the package substrate.

19. An image sensor package, comprising:
a package substrate including a plurality of upper pads;
an image sensor chip disposed on the package substrate, having first to fourth sides, and including a plurality of inactive chip pads adjacent to the first side and a plurality of active chip pads adjacent to the second to fourth sides, respectively;
a plurality of conductive wires each conductive wire electrically connecting an upper pad of the plurality of upper pads of the package substrate to a corresponding active chip pad of the plurality of active chip pads of the image sensor chip on each of the second to fourth sides of the image sensor chip;
a reinforcing structure disposed on the first side of the image sensor chip;
a dam disposed along the first to fourth sides of the image sensor chip, and covering at least a portion of each inactive chip pad of the plurality of inactive chip pads, each active chip pad of the plurality of active chip pads, the reinforcing structure and each conductive wire of the plurality of conductive wires;
a transparent cover disposed on the dam, and spaced apart from an upper surface of the image sensor chip; and
an encapsulant covering at least a portion of each of the image sensor chip, the dam and the transparent cover on the package substrate,
wherein the reinforcing structure includes a body portion, a lower adhesive film in contact with an upper surface of the image sensor chip below the body portion, and an upper adhesive film in contact with a lower surface of the transparent cover on the body portion, and
wherein the dam surrounds a side surface of each of the body portion, the lower adhesive film, and the upper adhesive film.

20. The image sensor package of claim 19, wherein a distance from the first side of the image sensor chip to the reinforcing structure is smaller than a distance from the first side of the image sensor chip to each inactive pad of the plurality of inactive chip pads.
